(19) United States
(12) Patent Application Publication
(10) Pub. No.: US 2026/0047103 A1
(43) Pub. Date: Feb. 12, 2026

(54) CROSS-POINT SPIN-ORBIT TORQUE MAGNETORESISTIVE MEMORY ARRAY AND METHOD OF MAKING THE SAME

(71) Applicant: Sandisk Technologies, Inc., Milpitas, CA (US)

(72) Inventors: Lei WAN, San Jose, CA (US); Yabin FAN, San Jose, CA (US)

(21) Appl. No.: 18/798,180

(22) Filed: Aug. 8, 2024

(51) Int. Cl. H10B 61/00; H10N 50/01; H10N 50/10; H10N 50/20; H10N 52/00; H10N 52/01; H10N 52/85

(52) U.S. Cl. CPC H10B 61/22; H10N 50/01; H10N 50/10; H10N 50/20; H10N 52/01; H10N 52/101; H10N 52/85; H10B 61/10

(57) ABSTRACT

A magnetoresistive memory device includes a substrate, a bottom pinned spin-orbit torque (SOT) memory cell located over the substrate, and including a first magnetic tunnel junction and a common SOT layer located on the first magnetic tunnel junction, and a top pinned SOT memory cell located over the bottom pinned SOT memory cell, and including a second magnetic tunnel junction located on the common SOT layer. The common SOT layer is shared between the top pinned SOT memory cell and the bottom pinned SOT memory cell.

### FIELD

The present disclosure relates generally to the field of magnetoresistive memory devices, and particularly to a cross-point spin-orbit torque (SOT) magnetoresistive memory array and methods of manufacturing the same.

### BACKGROUND

Spin-orbit torque (SOT) magnetoresistive random access memory (MRAM) devices (also known as magnetic random access memory devices) use switching of magnetization direction of a free magnetic layer by injection of an in-plane current in an adjacent conductive layer, which is referred to as a spin-orbit torque (SOT) layer. Unlike spin torque transfer (STT) magnetoresistive random access memory (MRAM) devices in which the write current flows through the magnetic tunnel junction, the write operation is performed by flowing an electric current through an adjacent conductive layer. The read operation of a SOT memory cell is performed by passing electric current through the magnetic tunnel junction of the SOT memory cell.

### SUMMARY

According to an aspect of the present disclosure, a magnetoresistive memory device includes a substrate; a bottom pinned spin-orbit torque (SOT) memory cell located over the substrate, and including a first magnetic tunnel junction and a common SOT layer located on the first magnetic tunnel junction; and a top pinned SOT memory cell located over the bottom pinned SOT memory cell, and including a second magnetic tunnel junction located on the common SOT layer. The common SOT layer is shared between the top pinned SOT memory cell and the bottom pinned SOT memory cell.

According to another aspect of the present disclosure, a magnetoresistive memory device comprises: first read lines laterally extending along a first horizontal direction and laterally spaced apart from each other along a second horizontal direction; a two-dimensional array of first pillar structures located on top surfaces of the first read lines, wherein each of the first pillar structures comprises a respective vertical stack including a respective first selector element and a respective first magnetic tunnel junction; first write lines located on top surfaces of the two-dimensional array of first pillar structures and laterally extending along the second horizontal direction and laterally spaced apart from each other along the first horizontal direction; a two-dimensional array of second pillar structures located on top surfaces of the first write lines, wherein each of the second pillar structures comprises a respective vertical stack including a respective second magnetic tunnel junction and a respective second selector element; and second read lines located on top surfaces of the two-dimensional array of second pillar structures and laterally extending along the first horizontal direction and laterally spaced apart from each other along the second horizontal direction, wherein each of the first magnetic tunnel junctions comprises a respective first reference layer, a respective first tunneling barrier layer, and a respective first free layer that is in contact with a respective one of the first write lines.

According to another aspect of the present disclosure, a method of forming a memory array comprises: forming first read lines laterally extending along a first horizontal direction and laterally spaced apart from each other along a second horizontal direction over a substrate; forming a two-dimensional array of first pillar structures over the first read lines, wherein each of the first pillar structures comprises a respective vertical stack including a respective first selector element and a respective first magnetic tunnel junction, and wherein each of the first magnetic tunnel junctions comprises a respective first reference layer, a respective first tunneling barrier layer, and a respective first free layer; forming first write lines over the two-dimensional array of first pillar structures, wherein the first write lines laterally extend along the second horizontal direction and are laterally spaced apart from each other along the first horizontal direction, and wherein each of the first write lines is formed directly on a column of a respective subset of the first free layers; forming a two-dimensional array of second pillar structures over the first write lines, wherein each of the second pillar structures comprises a respective vertical stack including a respective second magnetic tunnel junction and a respective second selector element; and forming second read lines over the two-dimensional array of second pillar structures, wherein the second read lines laterally extend along the first horizontal direction and are laterally spaced apart from each other along the second horizontal direction.

### BRIEF DESCRIPTION OF THE DRAWINGS

FIG. 1 is a schematic diagram of a memory device including an array of magnetoresistive memory cells according to an aspect of the present disclosure.

FIGS. 2A-2C are various views of an exemplary structure after formation of first read lines according to an aspect of the present disclosure. FIG. 2A is a top-down view, FIG. 2B is a vertical cross-sectional view along the vertical plane B-B′ of FIG. 2A, and FIG. 2C is a vertical cross-sectional view along the vertical plane C-C′ of FIG. 2A.

FIGS. 3A-3C are various views of an exemplary structure after formation of first pillar material layers according to an embodiment of the present disclosure. FIG. 3A is a top-down view, FIG. 3B is a vertical cross-sectional view along the vertical plane B-B′ of FIG. 3A, and FIG. 3C is a vertical cross-sectional view along the vertical plane C-C′ of FIG. 3A.

FIGS. 4A-4D are various views of the exemplary structure after formation of a first hard mask layer and a patterned photoresist material portions according to embodiments of the present disclosure. FIG. 4A is a top-down view, FIG. 4B is a vertical cross-sectional view along the vertical plane B-B′ of FIG. 4A, and FIG. 4C is a vertical cross-sectional view along the vertical plane C-C′ of FIG. 4A. FIG. 4D is a top-down view of an alternative configuration.

FIGS. 5A-5D are various views of the exemplary structure after formation of a two-dimensional array of first pillar structures according to an embodiment of the present disclosure. FIG. 5A is a top-down view, FIG. 5B is a vertical cross-sectional view along the vertical plane B-B′ of FIG. 5A, and FIG. 5C is a vertical cross-sectional view along the vertical plane C-C′ of FIG. 5A. FIG. 5D is a top-down view of an alternative configuration.

FIGS. 6A-6C are various views of the exemplary structure after formation of a first dielectric diffusion barrier layer according to an embodiment of the present disclosure. FIG. 6A is a top-down view, FIG. 6B is a vertical cross-sectional view along the vertical plane B-B′ of FIG. 6A, and FIG. 6C is a vertical cross-sectional view along the vertical plane C-C′ of FIG. 6A.

FIGS. 7A-7C are various views of the exemplary structure after formation of a first dielectric matrix layer according to an embodiment of the present disclosure. FIG. 7A is a top-down view, FIG. 7B is a vertical cross-sectional view along the vertical plane B-B′ of FIG. 7A, and FIG. 7C is a vertical cross-sectional view along the vertical plane C-C′ of FIG. 7A.

FIGS. 8A-8C are various views of the exemplary structure after performing a first planarization process according to an embodiment of the present disclosure. FIG. 8A is a top-down view, FIG. 8B is a vertical cross-sectional view along the vertical plane B-B′ of FIG. 8A, and FIG. 8C is a vertical cross-sectional view along the vertical plane C-C′ of FIG. 8A.

FIGS. 9A-9C are various views of the exemplary structure after formation of first write lines according to an embodiment of the present disclosure. FIG. 9A is a top-down view, FIG. 9B is a vertical cross-sectional view along the vertical plane B-B′ of FIG. 9A, and FIG. 9C is a vertical cross-sectional view along the vertical plane C-C′ of FIG. 9A.

FIGS. 10A-10C are various views of the exemplary structure after formation of second pillar material layers according to an embodiment of the present disclosure. FIG. 10A is a top-down view, FIG. 10B is a vertical cross-sectional view along the vertical plane B-B′ of FIG. 10A, and FIG. 10C is a vertical cross-sectional view along the vertical plane C-C′ of FIG. 10A.

FIGS. 11A-11D are various views of the exemplary structure after formation of a two-dimensional array of second pillar structures according to an embodiment of the present disclosure. FIG. 11A is a top-down view, FIG. 11B is a vertical cross-sectional view along the vertical plane B-B′ of FIG. 11A, and FIG. 11C is a vertical cross-sectional view along the vertical plane C-C′ of FIG. 11A. FIG. 11D is a top down view along horizontal plane D-D′ of FIG. 11B according to an alternative embodiment of the present disclosure,

FIGS. 12A-12C are various views of the exemplary structure after deposition and planarization of a second diffusion barrier layer and a second dielectric matrix layer according to an embodiment of the present disclosure. FIG. 12A is a top-down view, FIG. 12B is a vertical cross-sectional view along the vertical plane B-B′ of FIG. 12A, and FIG. 12C is a vertical cross-sectional view along the vertical plane C-C′ of FIG. 12A.

FIGS. 13A-13C are various views of the exemplary structure after formation of second read lines according to an embodiment of the present disclosure. FIG. 13A is a top-down view, FIG. 13B is a vertical cross-sectional view along the vertical plane B-B′ of FIG. 13A, and FIG. 13C is a vertical cross-sectional view along the vertical plane C-C′ of FIG. 13A.

FIG. 14A is a perspective view of the exemplary structure after formation of a two-dimensional array of third pillar structures, second write lines, a two-dimensional array of fourth pillar structures, and third read lines during a write operation according to an embodiment of the present disclosure.

FIG. 14B is a perspective view of the exemplary structure of FIG. 14A during a read operation according to an embodiment of the present disclosure.

### DETAILED DESCRIPTION

As discussed above, the present disclosure is directed to a cross-point spin-orbit torque (SOT) magnetoresistive memory array and methods of manufacturing the same, the various aspects of which are discussed herein in detail.

The drawings are not drawn to scale. Multiple instances of an element may be duplicated where a single instance of the element is illustrated, unless absence of duplication of elements is expressly described or clearly indicated otherwise. Same reference numerals refer to the same element or to a similar element. Elements having the same reference numerals are presumed to have the same material composition unless expressly stated otherwise. Ordinals such as “first,” “second,” and “third” are employed merely to identify similar elements, and different ordinals may be employed across the specification and the claims of the instant disclosure. As used herein, a first element located “on” a second element can be located on the exterior side of a surface of the second element or on the interior side of the second element. As used herein, a first element is located “directly on” a second element if there exist a physical contact between a surface of the first element and a surface of the second element. As used herein, an “in-process” structure or a “transient” structure refers to a structure that is subsequently modified.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the continuous structure. For example, a layer may be located between any pair of horizontal planes between, or at, a top surface and a bottom surface of the continuous structure. A layer may extend horizontally, vertically, and/or along a tapered surface. A substrate may be a layer, may include one or more layers therein, and/or may have one or more layer thereupon, thereabove, and/or therebelow.

As used herein, a “layer stack” refers to a stack of layers. As used herein, a “line” or a “line structure” refers to a layer that has a predominant direction of extension, i.e., having a direction along which the layer extends the most.

As used herein, a “conductive material” refers to a material having electrical conductivity greater than 1.0×10⁵ S/cm. As used herein, an “insulating material” or a “dielectric material” refers to a material having electrical conductivity less than 1.0×10⁻⁶ S/cm. As used herein, a “metallic material” refers to a conductive material including at least one metallic element therein. All measurements for electrical conductivities are made at the standard condition.

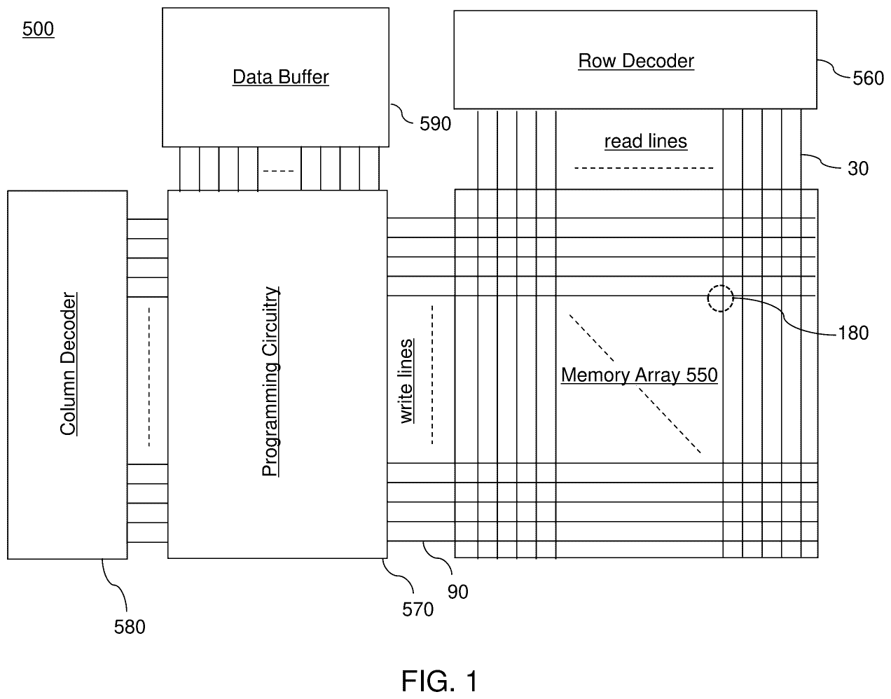

Referring to FIG. 1, a schematic diagram is shown for a magnetoresistive memory device 500 according to an embodiment of the present disclosure. The magnetoresistive memory device can be configured as a random access memory (RAM) device containing a three-dimensional array of magnetoresistive memory cells 180. As used herein, a “random access memory” device or a “RAM” device refers to a memory device containing memory cells that allow random access, e.g., access to any selected memory cell upon a command for reading the contents of the selected memory cell. As used herein, a “magnetoresistive random access memory” device or an “MRAM” device refers to a RAM device in which the memory cells are magnetoresistive memory cells.

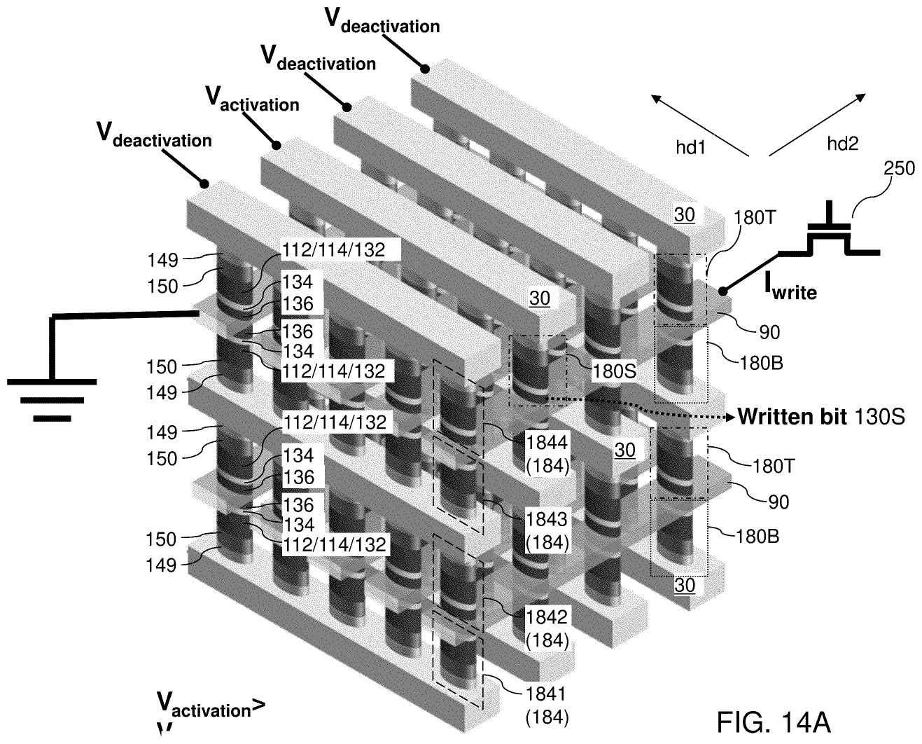

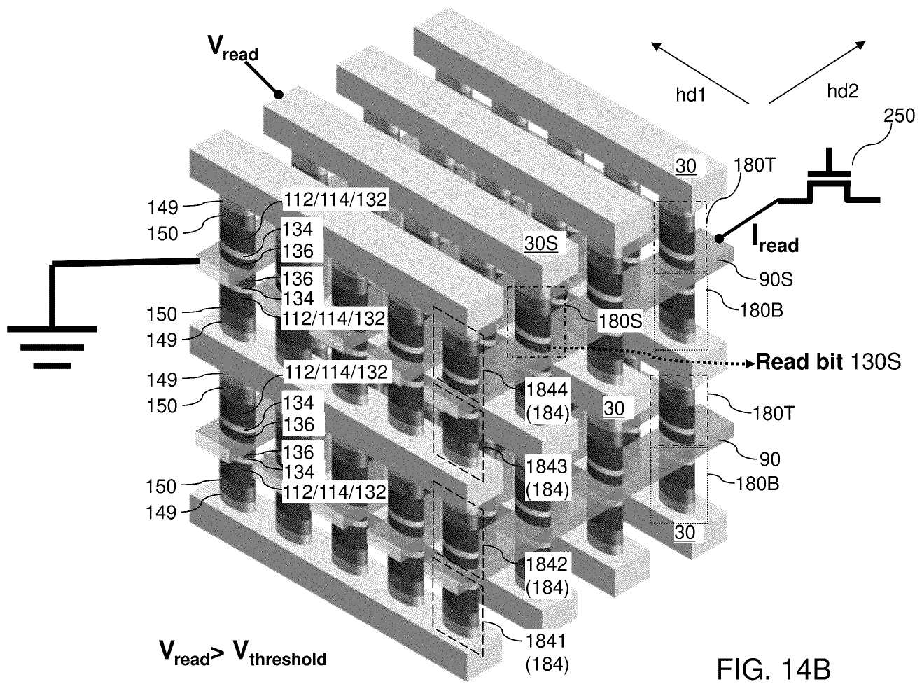

The magnetoresistive memory device 500 of an embodiment of the present disclosure includes a memory array region 550 containing a three-dimensional array of magnetoresistive memory cells 180, which in one embodiment comprise SOT memory cells. According to an aspect of the present disclosure, the three-dimensional array of magnetoresistive memory cells 180 may comprise a vertical stack of multiple two-dimensional arrays of magnetoresistive memory cells 180 that are accessed through multiple levels of first-type access lines (e.g., word lines) that are referred to herein as read lines, and through multiple levels of second-type access lines (e.g., bit lines) that are referred to herein as write lines. For example, upon labeling the levels of the read lines 30 and the levels of the write lines 90 with positive integers starting within 1 and incrementing with 1 in the order of proximity to an underlying substrate, the read lines 30 may be formed at odd-numbered levels and the write lines 90 may be formed at even numbered levels, as shown in FIGS. 14A and 14B.

The various levels of the read lines 30 may be numbered, from bottom to top, with positive integers starting with 1 and incrementing by 1. A subset of the read lines 30 that is formed at a first read line level may be referred to as first read lines 30, a subset of the read lines 30 that is formed at a second read line level may be referred to as second read lines 30, etc. The read lines 30 may laterally extend along a same horizontal direction, which is herein referred to as a first horizontal direction, hd1 (e.g., read line or word line direction). Likewise, the various levels of the write lines 90 may be numbered, from bottom to top, with positive integers starting with 1 and incrementing by 1. A subset of the write lines 90 that is formed at a first write line level may be referred to as first write lines 90, a subset of the write lines 90 that is formed at a second write line level may be referred to as second write lines 90, etc. The write lines 90 may laterally extend along a second horizontal direction hd2 (e.g., write line or bit line direction) that is different from the first horizontal direction. The second horizontal direction may be perpendicular to the first horizontal direction.

Within each two-dimensional array of magnetoresistive memory cells 180, each magnetoresistive memory cells 180 can be formed at an intersection point between a respective overlying access line (which may be a write line 90 or a read line 30) and a respective underling access line (which may be a read line 30 or a write line 90). One of the respective overlying access line and the respective underlying access line is a read line 30, and another of the respective overlying access line and the respective underlying access line is a write line 90. Thus, two SOT memory cells 180 located in different vertical levels share the same write line 90 and are formed upside down relative to each other (e.g., the lower SOT memory cell 180 is connected to a first read line 30 located below the lower SOT memory cell 180, while the upper SOT memory cell 180 is connected to a second read line 30 located above the upper SOT memory cell 180, and the shared write line 90 is vertically located between the upper and the lower SOT memory cells 180).

The magnetoresistive memory device 500 may also contain a row decoder 560 connected to the read lines, a programming circuitry 570 connected to the write lines, a column decoder 580 configured to decode the address for the write lines, and a data buffer 590 connected to the programming circuitry 570.

As used herein, a SOT memory cell 180 refers to a type of memory cell used in spintronic devices where data storage and manipulation are achieved through spin-orbit torque. In these cells, a nonmagnetic heavy metal SOT layer with strong spin-orbit coupling is in contact with a magnetic free layer. When the electric write current is passed laterally through the SOT layer, spin current is generated in a direction perpendicular to the electric write current via the spin Hall effect (SHE), exerting a torque on the magnetization of the free layer and switching the magnetization direction of the free layer, which can be either upward or downward in the vertical direction. The free layer is part of a magnetic tunnel junction (MTJ) which includes a tunneling dielectric layer located between the free layer and a magnetic reference layer (i.e., the pinned magnetic layer having a fixed magnetization direction). The free layer can be programmed to have its magnetization direction either parallel or antiparallel to the magnetization direction of the reference layer by the write current on the SOT layer. When the magnetization direction of the free layer is parallel to that of the reference layer, the MTJ exhibits a low resistance state, representing a binary “0” or “1” depending on the configuration. Conversely, when the magnetization direction of the free layer is antiparallel to the reference layer, the MTJ exhibits a high resistance state, representing the opposite binary value.

Further, each SOT memory cell 180 may comprise a selector element that is connected to the MTJ in series. The selector element may comprise a two-terminal selector element located between the MTJ and the respective read line 30 of the SOT memory cell 180. Thus, each SOT memory cell 180 can be accessed through a unique combination of a read line 30 and a write line 90.

The read mechanism of each SOT memory cell is based on the tunnel magnetoresistance (TMR) effect. The TMR effect occurs in the magnetic tunnel junction (MTJ) when electrons tunnel through the tunneling dielectric layer between the reference layer and the free layer. The resistance of the MTJ changes depending on the relative orientation of the magnetization directions of the reference layer and the free layer. When the magnetization directions of the reference layer and the free layer are parallel, the MTJ exhibits a low resistance state due to a higher probability of electron tunneling. Conversely, when the magnetization directions are antiparallel, the MTJ exhibits a high resistance state due to a lower probability of electron tunneling. This change in resistance is detected and interpreted as binary data (e.g., “0” or “1”).

In one embodiment, each free layer is directly contacted by a horizontal surface of a respective write line 90. The programming circuitry 570 provides the electric write current along the write lines 90. The write current that flows through a selected write line 90 can induce a spin current that interacts with the magnetic moments of the free layer of the selected SOT memory cell 180 if the read line 30 of the selected SOT memory cell 180 is electrically biased at a suitable bias voltage (which is herein referred to as a read line activation voltage). The activation voltage induces a voltage differential across the tunneling dielectric layer through the respective two terminal selector element and the reference layer of the selected SOT memory cell 180. Thus, the embodiment SOT memory cells 180 are referred to a voltage controlled magnetic anisotropy (VCMA) controlled SOT memory cells 180. The remaining read lines 30 of unselected SOT memory cells 180 that share the selected write line 90 with the selected SOT memory cell 180 are electrically biased at another voltage (which is herein referred to as a read line deactivation voltage) that does not induce a voltage differential across the tunneling dielectric layers of the unselected SOT memory cells 180. The deactivation voltage inhibits writing (i.e., switching the magnetization direction of the free layer) of the unselected SOT memory cells 180 that share the same write line 90 with the selected SOT memory cell 180.

A read voltage is applied to the selected SOT memory cell 180 between its read line 30 and its write line 90 using the row decoder 560 and optionally the programing circuitry 570. For a read voltage above the threshold voltage of the selector and MTJ, the electric read current flows through the selected SOT memory cell 180 is determined by whether the magnetization of the free layer is parallel to, or is antiparallel to, the magnetization of the reference layer by a sensing circuit which may be embedded in the programming circuitry 570. Thus, the data stored in the selected SOT memory cell 180, as encoded as the direction of magnetization of its free layer, can be read by performing the read operation.

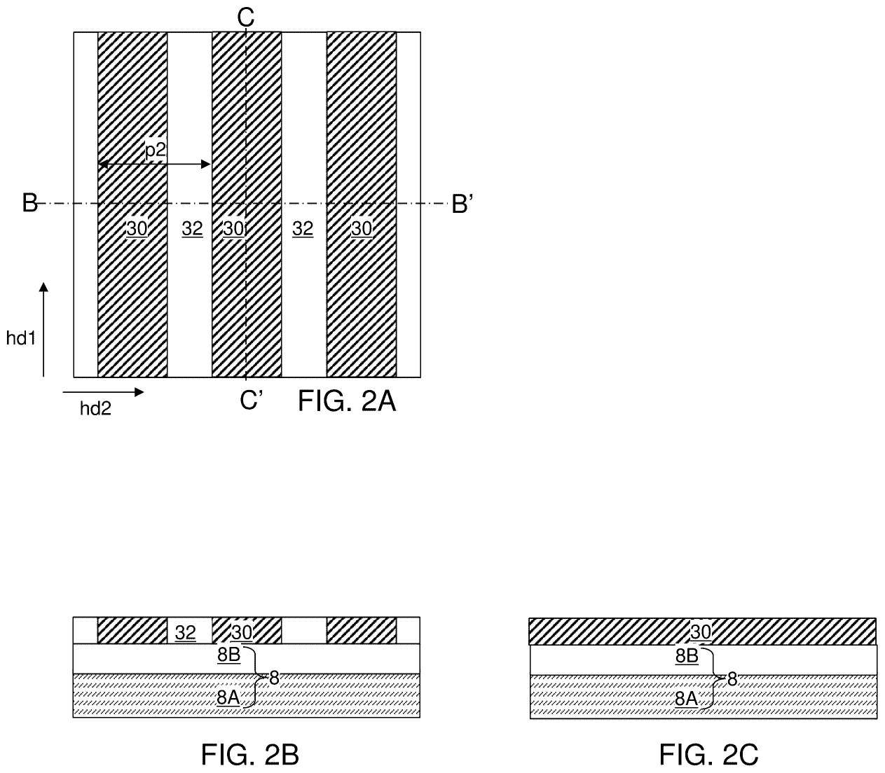

Referring to FIGS. 2A-2C, an exemplary structure is illustrated after formation of first read lines 30. The exemplary structure comprises a substrate 8. The substrate 8 may comprise, for example, a semiconductor substrate 8A and at least one dielectric material layer 8B formed over the semiconductor substrate 8A. Alternatively, an insulating substrate (e.g., a ceramic or a glass substrate) or a conductive substrate (e.g., a metal or metal alloy substrate) may be used instead. In one embodiment, various semiconductor devices (not shown) including switching devices and peripheral (i.e., driver) circuits may be formed over the semiconductor substrate 8A, and metal interconnect structures (not shown) may be formed in the at least one dielectric material layer 8B. The various semiconductor devices, if present, may comprise the various driver circuits of the MRAM device 500 illustrated in FIG. 1 other than the memory array region 550, which is subsequently formed in subsequent processing steps.

A first read line-level dielectric layer 32 can be deposited over the substrate 8, and line trenches laterally extending along the first horizontal direction hd1 can be formed through the first read line-level dielectric layer 32. A conductive material can be deposited in the line trenches, and excess portions of the conductive material can be removed from above the horizontal plane including the top surface of the first read line-level dielectric layer 32. Remaining portions of the conductive material filling the line trenches constitute first read lines 30. The first read lines 30 comprise and/or consist essentially of a nonmagnetic electrically conductive material such as Al, Cu, W, Ru, Mo, Nb, Ti, Ta, TiN, TaN, WN, MoN, or combinations thereof. The thickness of the first read lines 30 can be in a range from 20 nm to 100 nm, although lesser and greater thicknesses can also be employed.

Alternatively, instead of using the above-described damascene process to form the first read lines 30, these lines may be formed by a pattern and etch process. In the pattern and etch process, a continuous electrically conductive layer is patterned into the first read lines 30 by photolithography and etching. The first read line-level dielectric layer 32 is then deposited between the first read lines 30 and optionally planarized with the top surfaces of the first read lines 30.

The first read lines 30 laterally extend along the first horizontal direction hd1, and may be laterally spaced apart from each other along a second horizontal direction hd2. The first read lines 30 may be formed as a one-dimensional periodic array of first read lines 30 having a second pitch p2 along the second horizontal direction hd2. The second pitch p2 may be in a range from 10 nm to 300 nm, although lesser and greater dimensions may also be employed. In one embodiment, the remaining portions of the first read line-level dielectric layer 32 may comprise first dielectric rails laterally extending along the first horizontal direction hd1, and interlaced with the first read lines 30 along the second horizontal direction hd2.

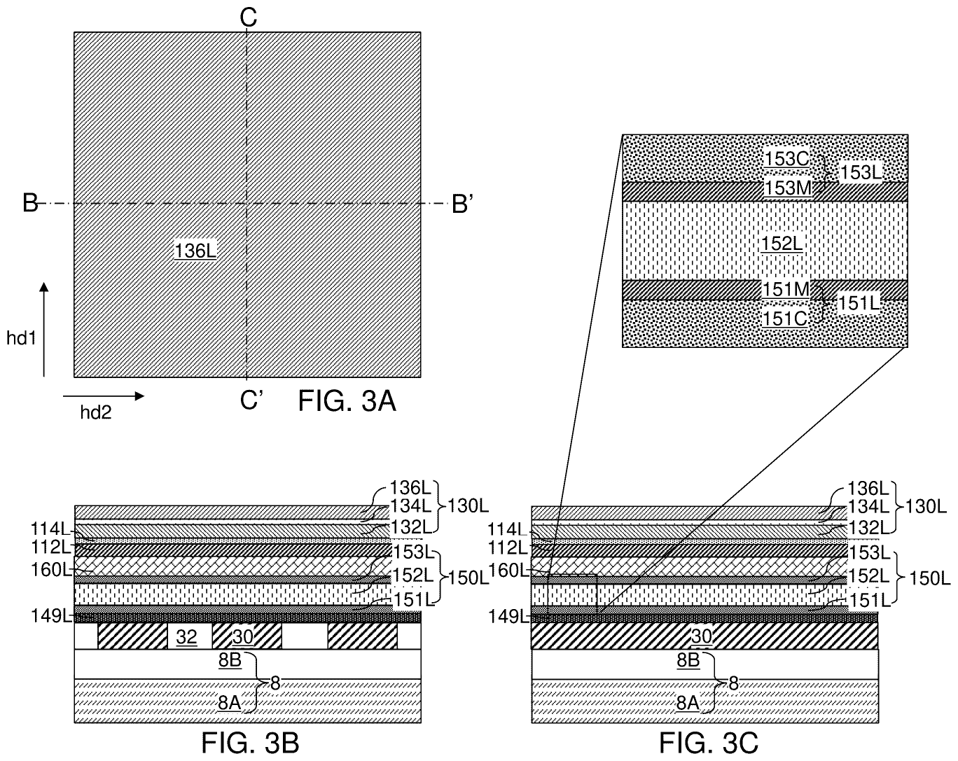

Referring to FIGS. 3A-3C, first pillar material layers (149L, 150L, 160L, 112L, 114L, 130L) can be deposited over the first read lines 30. The first pillar material layers (149L, 150L, 160L, 112L, 114L, 130L) may comprise, from bottom to top, an optional first metallic adhesion (e.g., buffer) layer 149L, first selector-level material layers (150L, 160L), a first continuous synthetic antiferromagnetic layer 112L, a first continuous antiferromagnetic coupling layer 114L, and first magnetic tunnel junction layers 130L. The first pillar material layers may be annealed after deposition.

The optional first metallic adhesion layer 149L comprises a metallic material that promotes adhesion of the first selector-level material layers (150L, 160L). For example, the optional first metallic adhesion layer 149L may comprise a metallic material, such as Ta, Ti, TaN, TiN, or WN. The thickness of the first metallic adhesion layer 149L may be in a range from 1 nm to 30 nm, although lesser and greater thicknesses may also be employed.

The first selector-level material layers (150L, 160L) can include, from bottom to top, first selector material layers 150L and an optional first electrically conductive layer 160L. The first selector material layers 150L can comprise, from bottom to top, a distal selector electrode material layer 151L, a non-Ohmic material layer 152L, and a proximal selector electrode material layer 153L. The distal selector electrode material layer 151L includes at least one material that may be employed for distal selector electrodes to be subsequently formed. The non-Ohmic material layer 152L includes a selector material that exhibits a non-Ohmic switching behavior. The proximal selector electrode material layer 153L includes at least one material that may be employed proximal selector electrodes to be subsequently formed.

In one embodiment, the distal selector electrode material layer 151L may comprise a layer stack including a lower carbon-based electrode material layer 151C and a lower metallic material layer 151M formed on the lower carbon-based electrode material layer 151C. In one embodiment, the proximal selector electrode material layer 153L may comprise a layer stack including an upper metallic material layer 153M and an upper carbon-based electrode material layer 153C formed on the upper metallic material layer 153M.

The lower carbon-based electrode material layer 151C and the upper carbon-based electrode material layer 153C within the first selector-level material layers can include a respective carbon-based conductive material including carbon atoms at an atomic concentration greater than 50%. In one embodiment, the lower carbon-based electrode material layer 151C and the upper carbon-based electrode material layer 153C may include carbon atoms at an atomic concentration in a range from 50% to 100%, such as from 70% to 100% and/or from 80% to 100%. In one embodiment, each of the lower carbon-based electrode material layer 151C and the upper carbon-based electrode material layer 153C comprises a respective material selected from a carbon nitride material, and a carbon-rich conductive compound of carbon atoms and non-carbon atoms. Each of the lower carbon-based electrode material layer 151C and the upper carbon-based electrode material layer 153C may have a respective thickness in a range from 3 nm to 300 nm, although lesser and greater thicknesses may also be employed.

The lower metallic material layer 151M and the upper metallic material layer 153M within the first selector material layers 150L can include a respective metallic material having electrical conductivity that is greater than the electrical conductivity of the carbon-based conductive materials of the lower carbon-based electrode material layer 151C and the upper carbon-based electrode material layer 153C. In one embodiment, the lower metallic material layer 151M comprises a metallic material having electrical conductivity that is at least 10 times (which may be at least 30 times and/or at least 100 times and/or at least 1,000 times) the electrical conductivity of the carbon-based conductive material of lower carbon-based electrode material layer 151C, and the upper metallic material layer 153M comprises a second metallic material having electrical conductivity that is at least 10 times (which may be at least 30 times and/or at least 100 times and/or at least 1,000 times) the electrical conductivity of the carbon-based conductive material of the upper carbon-based electrode material layer 153C.

Generally, each of the lower metallic material layer 151M and the upper metallic material layer 153M may comprise, and/or may consist essentially of, a high-conductivity metallic material that has a high electrical conductivity, and thus, is capable of functioning as a current-spreading material that prevents concentration of electric current in the non-Ohmic material of the non-Ohmic material layer 152L. In one embodiment, the lower metallic material layer 151M and/or the upper metallic material layer 153M may comprise, and/or may consist essentially of, an elemental metal, a conductive metallic carbide, or a conductive metallic nitride. In one embodiment, the lower metallic material layer 151M and/or the upper metallic material layer 153M may comprise, and/or may consist essentially of, a respective elemental metal having a melting point higher than 2,000 degrees Celsius (such as refractory metals). In one embodiment, the lower metallic material layer 151M and/or the upper metallic material layer 153M may comprise, and/or may consist essentially of, a respective elemental metal selected from ruthenium, niobium, molybdenum, tantalum, tungsten, or rhenium. In one embodiment, the lower metallic material layer 151M and/or the upper metallic material layer 153M may comprise, and/or may consist essentially of, a conductive metallic carbide such as tungsten carbide. In one embodiment, the lower metallic material layer 151M and/or the upper metallic material layer 153M may comprise, and/or may consist essentially of, a conductive metallic nitride such as tungsten nitride, titanium nitride, or tantalum nitride.

Generally, the lower metallic material layer 151M and the upper metallic material layer 153M may have a lower thickness than the lower carbon-based electrode material layer 151C and the upper carbon-based electrode material layer 153C. Each of the lower metallic material layer 151M and the upper metallic material layer 153M may have a respective thickness in a range from 0.2 nm to 10 nm, such as from 1 nm to 5 nm, although lesser and greater thicknesses may also be employed. In one embodiment, the ratio of the thickness of the lower carbon-based electrode material layer 151C to the thickness of the lower metallic material layer 151M may be in a range from 3.0 to 500, such as from 10 to 100, although lesser and greater ratios may also be employed. In one embodiment, the ratio of the thickness of the upper carbon-based electrode material layer 153C to the thickness of the upper metallic material layer 153M may be in a range from 3.0 to 500, such as from 10 to 100, although lesser and greater ratios may also be employed. In an alternative embodiment, the lower metallic material layer 151M and the upper metallic material layer 153M may be omitted to form carbon-based electrode material layers 151L and 153L. In another alternative embodiment, the lower carbon-based electrode material layer 151C and the upper carbon-based electrode material layer 153C may be omitted to form metallic electrode material layers 151L and 153L.

In one embodiment, the non-Ohmic material layer 152L within the first selector material layers 150L can include any suitable non-Ohmic selector material which exhibits non-linear electrical behavior. For example, the non-Ohmic selector material may comprise an ovonic threshold switch (OTS) material. As used herein, an ovonic threshold switch material refers to a material that displays a non-linear resistivity curve under an applied external bias voltage such that the resistivity of the material decreases with the magnitude of the applied external bias voltage. In other words, the ovonic threshold switch material is non-Ohmic, and becomes more conductive under a higher external bias voltage than under a lower external bias voltage. As used herein, an ovonic threshold switch is a device that includes a chalcogen-containing ovonic threshold switch material layer which does not crystallize in a low resistivity state under a voltage above the threshold voltage, and reverts back to a high resistivity state when not subjected to a voltage above a critical holding voltage across the ovonic threshold switch material layer.

In another embodiment, the non-Ohmic selector material may comprise a volatile conductive bridge material or at least one non-threshold switch material, such as a tunneling selector material or diode materials (e.g., materials for p-n semiconductor diode, p-i-n semiconductor diode, Schottky diode, or metal-insulator-metal diode). Thus, the material layer 152L may comprise a diode layer stack, such as a layer stack of p-doped semiconductor material layer and an n-doped semiconductor material layer, or a layer stack of a p-doped semiconductor material layer, an intrinsic semiconductor material layer, and an n-doped semiconductor material layer.

An ovonic threshold switch material (OTS material) can be non-crystalline (for example, amorphous) in a high resistivity state, and can remain non-crystalline (for example, remain amorphous) in a low resistivity state during application of a voltage above its threshold voltage across the OTS material. The ovonic threshold switch material can revert back to the high resistivity state when the high voltage above its threshold voltage is lowered below a critical holding voltage. Throughout the resistivity state changes, the ovonic threshold switch material can remain non-crystalline (e.g., amorphous). In one embodiment, the ovonic threshold switch material can comprise an amorphous chalcogenide material, such as a GeSeAs alloy, a GeSeAsTe alloy, a GeTeAs alloy, a GeSeTe alloy, a GeSe alloy, a SeAs alloy, an AsTe alloy, a GeTe alloy, a SiTe alloy, a SiAsTe alloy, or a SiAsSe alloy. The chalcogenide material may be undoped or doped with at least one of N, O, C, P, Ge, As, Te, Se, In, or Si. The thickness of the non-Ohmic material layer 152L can be, for example, in a range from 1 nm to 50 nm, such as from 5 nm to 25 nm, although lesser and greater thicknesses can also be employed.

The optional first electrically conductive layer 160L includes a nonmagnetic conductive material, such as Ta and/or Pt, which can function as a seed layer for the magnetic-tunnel-junction-level (MTJ-level) material layers to be formed thereon. The thickness of the first electrically conductive layer 160L can be in a range from 1 nm to 10 nm, although lesser and greater thicknesses may also be employed. Alternatively, the first electrically conductive layer 160L may be omitted.

The first continuous synthetic antiferromagnetic layer 112L may comprise at least one material layer that can fix the magnetization direction of the first continuous reference layer 132L. The first continuous synthetic antiferromagnetic layer 112L may comprise a Co/Pt, Co/Pd or Co/Ni superlattice or a permanent magnet material layer. If the Co/Pt, Co/Pd, or Co/Ni superlattice is used, then the number of repetitions of a repetition unit (i.e., a bilayer stack) may be in a range from 2 to 20, although lesser and greater numbers of repetition may also be used.

The first continuous antiferromagnetic coupling layer 114L, if present, can provide antiferromagnetic coupling between a first continuous reference layer 132L within the first magnetic tunnel junction layers 130L and a most proximal ferromagnetic material layer within the first continuous synthetic antiferromagnetic layer 112L. In one embodiment, the first continuous antiferromagnetic coupling layer 114L may comprise ruthenium, iridium, or an IrMn alloy, and may have a thickness in a range from 0.5 nm to 4 nm.

The first magnetic tunnel junction layers 130L comprise, from bottom to top, the first continuous reference layer 132L, a first continuous tunneling barrier layer 134L, and a first continuous free layer 136L.

The first continuous reference layer 132L comprises a ferromagnetic material. In one embodiment, the first continuous reference layer 132L can include a CoFe alloy or a CoFeB alloy. Optionally, the first continuous reference layer 132L may additionally include a thin non-magnetic layer comprised of tantalum or tungsten having a thickness in a range from 0.2 nm to 0.5 nm and a thin CoFeB layer having a thickness in a range from 0.5 nm to 3 nm.

The first continuous tunneling barrier layer 134L includes any insulating tunnel barrier material, such as magnesium oxide, aluminum oxide, a spinel, etc. The thickness of the first continuous tunneling barrier layer 134L can be 0.7 nm to 1.3 nm, such as about 1 nm.

The first continuous free layer 136L comprises a ferromagnetic material. In one embodiment, the first continuous free layer 136L can include a CoFe alloy or a CoFeB alloy.

For example, the first continuous free layer 136L may comprise a CoFeB layer having a thickness in a range from 0.5 nm to 3 nm.

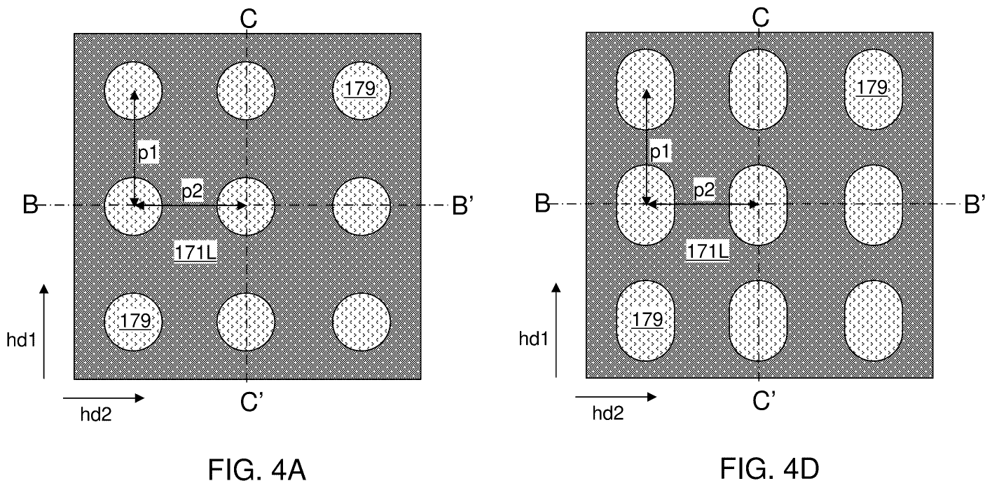

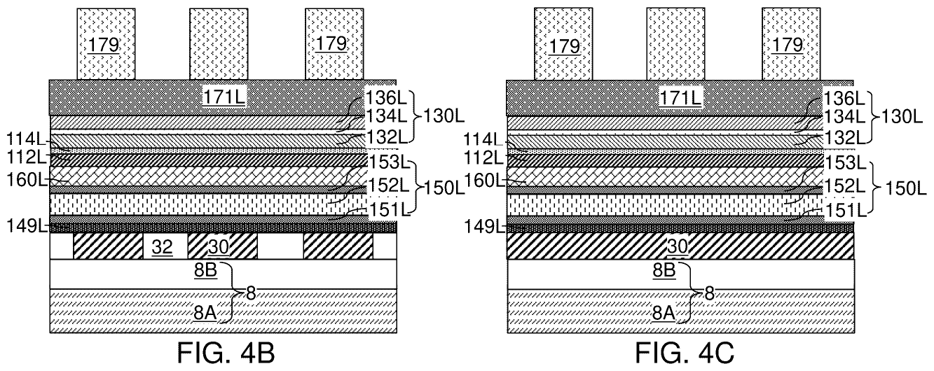

Referring to FIGS. 4A-4C, a first hard mask layer 171L can be deposited over the first pillar material layers (149L, 150L, 160L, 112L, 114L, 130L). The first hard mask layer 171L comprises a hard mask material such as silicon nitride, silicon carbide, silicon carbonitride, and/or a dielectric metal oxide. The thickness of the first hard mask layer 171L may be in a range from 10 nm to 150 nm, such as from 50 nm to 100 nm, although lesser and greater thicknesses may also be employed. Alternatively, the first hard mask layer 171L may comprise a sacrificial sublayer located below a hard mask sublayer.

A first photoresist layer can be applied over the first hard mask layer 171L, and can be lithographically patterned to form a two-dimensional periodic array of first patterned photoresist material portions 179. Each row of first patterned photoresist material portions 179 may have an area that is located entirely within the area of a respective underlying first read line 30 in a plan view, such as the top-down view of FIG. 4A. Each first patterned photoresist material portion 179 may have a respective shape of a circle (as shown in FIG. 4A), an ellipse, a rectangle, a rounded rectangle, or any other two-dimensional shape having a closed periphery. In an alternative embodiment shown in FIG. 4D, the first patterned photoresist material portion 179 may have a respective shape of the ellipse that is elongated along the first horizontal direction hd1. The two-dimensional array of first patterned photoresist material portions 179 may have a first pitch p1 along the first horizontal direction hd1, and may have the second pitch p2 along the second horizontal direction hd2.

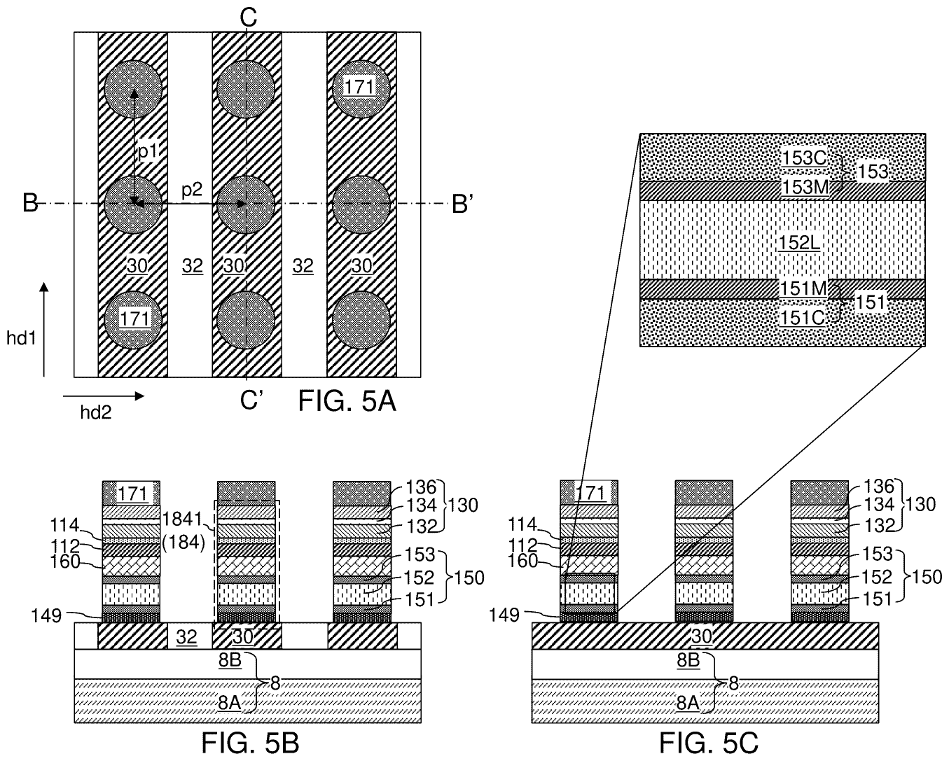

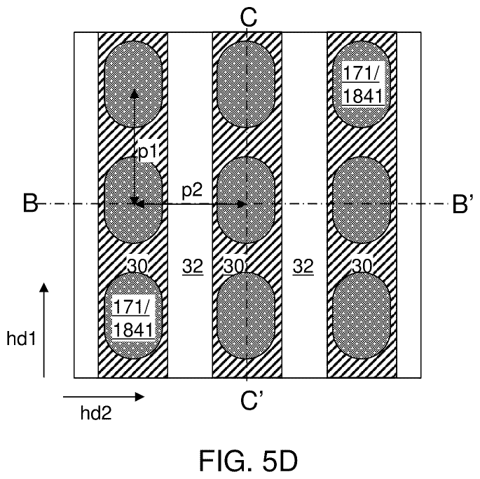

Referring to FIG. 5A-5D, at least one anisotropic etch process can be performed to transfer the pattern in the two-dimensional array of first patterned photoresist material portions 179 through the first hard mask layer 171L and through the first pillar material layers (149L, 150L, 160L, 112L, 114L, 130L). For example, a reactive ion etch process can be performed to transfer the pattern in the two-dimensional array of first patterned photoresist material portions 179 into the first hard mask layer 171L. The first hard mask layer 171L can be patterned into a two-dimensional array of first hard mask plates 171. The two-dimensional array of first patterned photoresist material portions 179 can be subsequently removed, for example, by ashing.

The two-dimensional array of first hard mask plates 171 can be employed as an etch mask to remove unmasked portions of the first pillar material layers (149L, 150L, 160L, 112L, 114L, 130L). At least one anisotropic etch process, such as an ion beam etch process and/or a reactive ion etch process, may be employed to etch the unmasked portions of the first pillar material layers (149L, 150L, 160L, 112L, 114L, 130L). For example, an ion beam etch process may be employed to pattern the first magnetic tunnel junction layers 130L, the first continuous antiferromagnetic coupling layer 114L, the first continuous synthetic antiferromagnetic layer 112L, and the first electrically conductive layer 160L. At least one anisotropic etch process may be employed to etch the first selector material layers 150L and the first metallic adhesion layer 149L. The patterned portions of the first pillar material layers (149L, 150L, 160L, 112L, 114L, 130L) comprise a two-dimensional array of first pillar structures 1841. The two-dimensional array of first pillar structures 1841 is a first subset of all pillar structures 184 that formed in the exemplary structure by the end of the processing steps employed to form a three-dimensional memory array. Each of the first pillar structures 1841 comprises a lower portion of a bottom pinned SOT memory cell 180 that will also include an additional overlying SOT layer, as will be described below.

The two-dimensional array of first pillar structures 1841 is formed over the first read lines 30. Each of the first pillar structures 1841 comprises a respective vertical stack including, from bottom to top, an optional first metallic adhesion plate 149, a first selector element 150, an optional first electrically conductive plate 160, a first synthetic antiferromagnetic structure 112, a first antiferromagnetic coupling layer 114, and a first magnetic tunnel junction 130. The first magnetic tunnel junction 130 may comprise a first reference layer 132, a first tunneling dielectric layer 134, and a first free layer 136., Each first metallic adhesion plate 149 is a patterned portion of the first metallic adhesion layer 149L; each first selector element 150 is a patterned portion of the first selector material layers 150L; each first electrically conductive plate 160 is a patterned portion of the first electrically conductive layer 160L, each first synthetic antiferromagnetic structure 112 is a patterned portion of the first continuous synthetic antiferromagnetic layer 112L; each first antiferromagnetic coupling layer 114 is a patterned portion of the first continuous antiferromagnetic coupling layer 114L; and each first magnetic tunnel junction 130 is a patterned portion of the first magnetic tunnel junction layers 130L.

Each first reference layer 132 is a patterned portion of the first continuous reference layer 132L; each first tunneling dielectric layer 134 is a patterned portion of the first continuous tunneling dielectric layer 134L; and each first free layer 136 is a patterned portion of the first continuous free layer 136L.

Patterned portions of the first selector material layers 150L comprise a two-dimensional array of first selector elements 150. Each first selector element 150 is a patterned portion of the first selector material layers 150L. Each first selector element 150 may include a vertical stack of a distal selector electrode 151, a non-Ohmic selector material plate 152, and a proximal selector electrode 153. Each distal selector electrode 151 is a patterned portion of the distal selector electrode material layer 151L. Each non-Ohmic selector material plate 152 is a patterned portion of the non-Ohmic material layer 152L. Each proximal selector electrode 153 is a patterned portion of the proximal selector electrode material layer 153L.

In summary, each first pillar structure 1841 comprises a vertical stack including, from bottom to top, a respective first selector element 150 and a respective first magnetic tunnel junction 130. Each of the first magnetic tunnel junctions 130 comprises a respective first reference layer 132, a respective first tunneling barrier layer 134, and a respective first free layer 136. In one embodiment, each of the first pillar structures 1841 comprises a respective first straight sidewall that extends from a top surface of a respective one of the first read lines 30 to a horizontal plane including the topmost surfaces of the first magnetic tunnel junctions 130.

In one embodiment, each of the first pillar structures 1841 also comprises a respective synthetic antiferromagnetic structure (“SAF”) (112, 114) that is located between the respective first reference layer 132 and the first selector element 150 and is antiferromagnetically coupled to the respective first reference layer 132. In one embodiment, each of the first selector elements 150 comprises a respective first ovonic threshold switch which comprises the non-Ohmic selector material plate 152). Within each of the first pillar structures 1841, the respective first selector element 150 underlies the respective first magnetic tunnel junction 130. In one embodiment, each of the first selector elements 150 is in electrical contact with a respective one of the first read lines 30.

In an alternative embodiment shown in FIG. 5D, each of the first pillar structures 1841 may be elongated along the first horizontal direction hd1. This configuration is advantageous for increasing the spin Hall effect, and thus, reduces the required duration of electric current flow for programming operations.

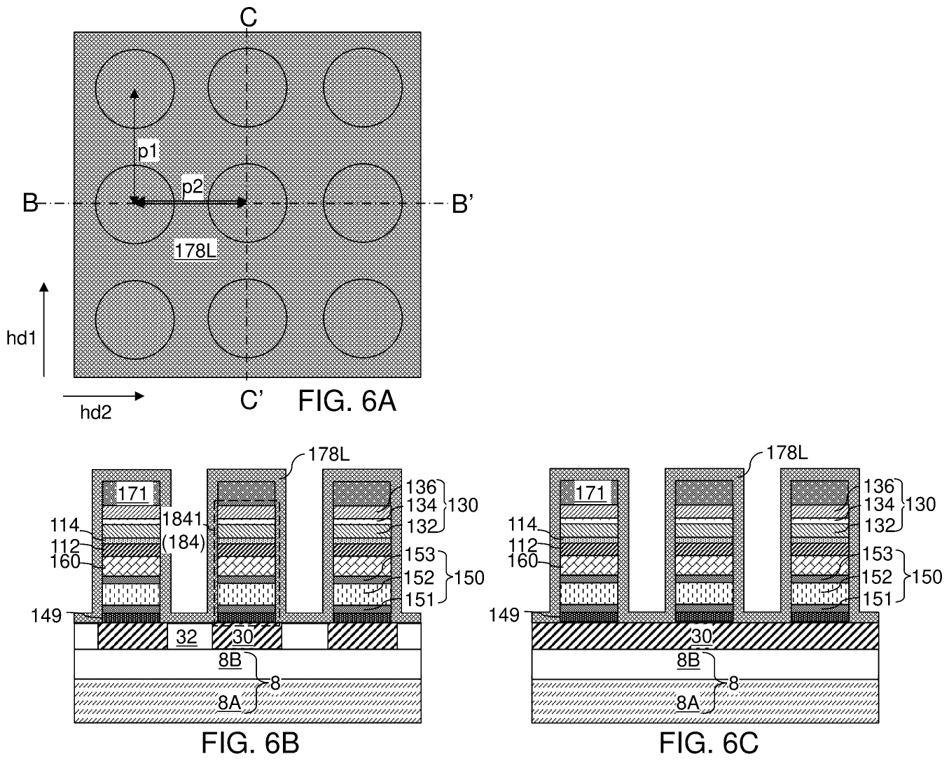

Referring to FIG. 6A-6C, an optional first dielectric diffusion barrier layer 178L can be conformally deposited over the first read lines 30 and the first read line-level dielectric layer 32 and around the two-dimensional array of first pillar structures 1841. The first dielectric diffusion barrier layer 178L comprises a dielectric diffusion barrier material, such as silicon nitride or silicon carbonitride. The thickness of the first dielectric diffusion barrier layer 178L may be in a range from 5 nm to 50 nm, although lesser and greater thicknesses may also be employed.

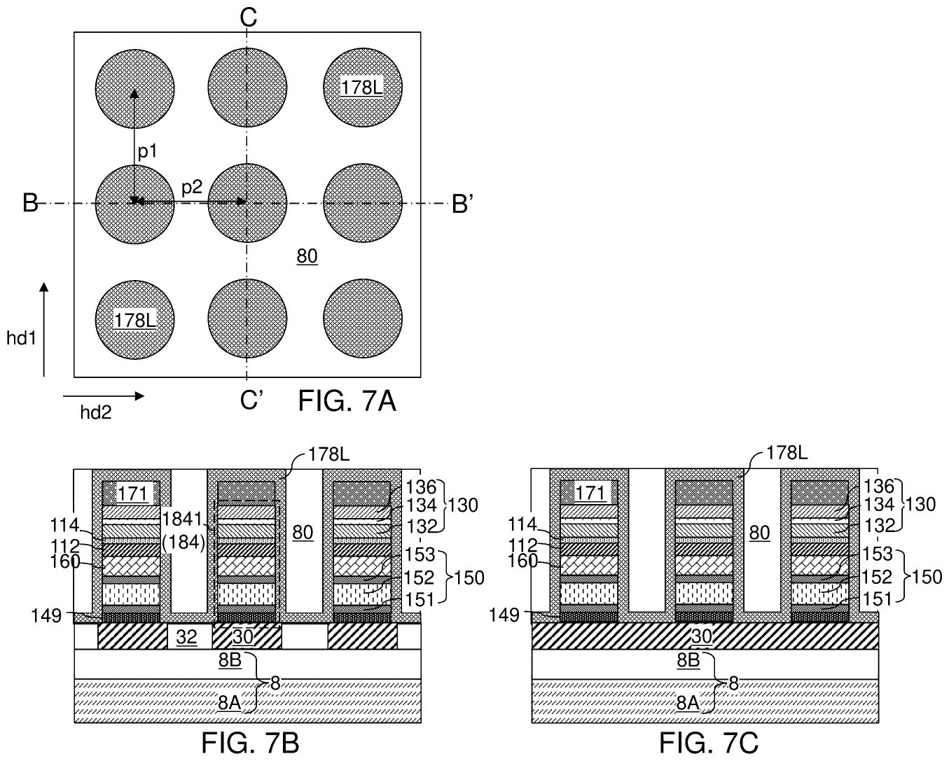

Referring to FIG. 7A-7C, a first dielectric fill material can be deposited in the gaps between neighboring vertically-extending portions of the first dielectric diffusion barrier layer 178L (if present) or in the gaps between the first pillar structures 1841 (if layer 178L is omitted). The first dielectric fill material may comprise a planarizable dielectric material, such as undoped silicate glass (i.e., silicon oxide) or a doped silicate glass. A planarization process can be performed to remove portions of the first dielectric fill material at least from above the horizontal plane including the topmost surfaces of the first dielectric diffusion barrier layer 178L (if present) or the hard mask plates 171 (if layer 178L is omitted). For example, a chemical mechanical polishing process can be performed to remove the first dielectric fill material from above the horizontal plane including the topmost surfaces of the first dielectric diffusion barrier layer 178L or the hard mask plates 171. The first dielectric diffusion barrier layer 178L or the hard mask plates 171 may function as a polish stop layer during the polishing. The remaining portion of the first dielectric fill material constitutes a first dielectric matrix layer 80.

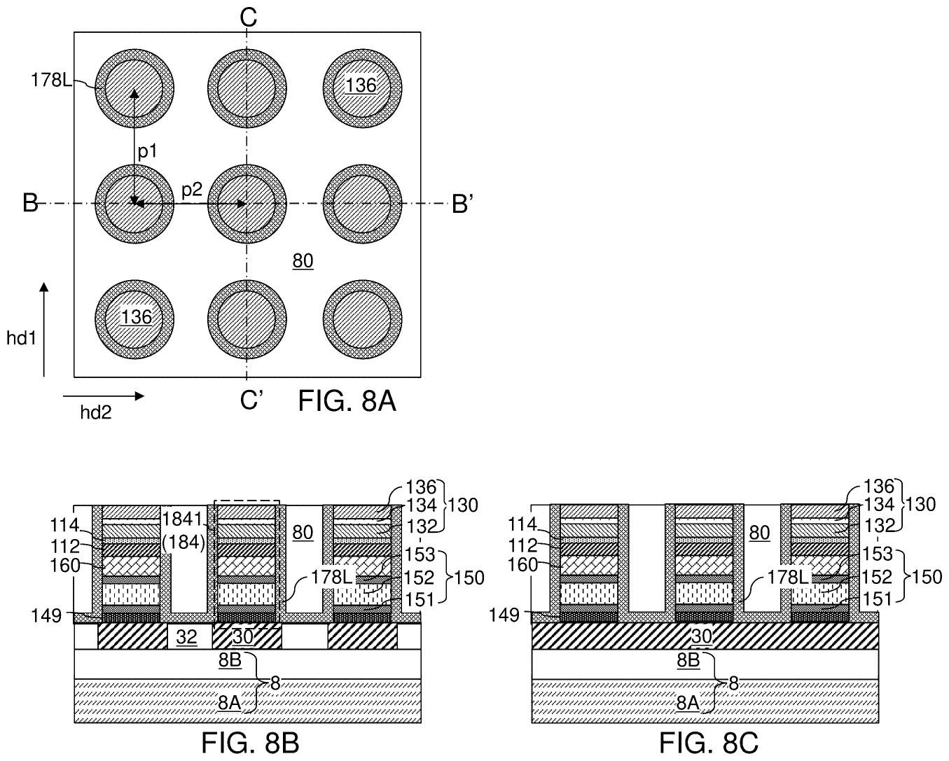

Referring to FIG. 8A-8C, a selective recess etch process and/or an additional chemical mechanical polishing process can be performed to vertically recess the first dielectric matrix layer 80 to the height of the bottom surfaces of the first hard mask plates 171. For example, a timed wet etch process employing dilute hydrofluoric acid can be performed to vertically recess the first dielectric matrix layer 80. Subsequently, the first hard mask plates 171 and the portions of the first dielectric diffusion barrier layer 178L that overlie the horizontal plane including the topmost surfaces of the first magnetic tunnel junctions 130 can be removed by performing a selective etch process that etches the materials of the first hard mask plates 171 and the portions of the first dielectric diffusion barrier layer 178L selectively to the materials of the first dielectric matrix layer 80 and the first free layers 136. For example, if the first hard mask plates 171 and the first dielectric diffusion barrier layer 178L comprise silicon nitride, a timed wet etch process employing hot phosphoric acid may be performed to remove the first hard mask plates 171 and the portions of the first dielectric diffusion barrier layer 178L that overlie the horizontal plane including the topmost surfaces of the first magnetic tunnel junctions 130.

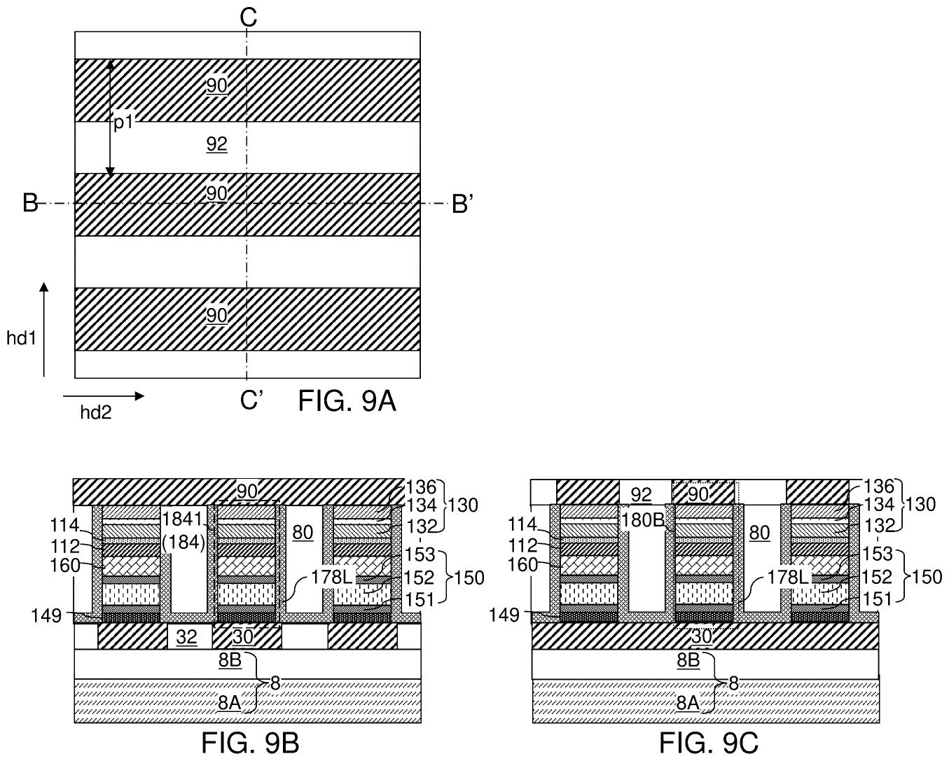

Referring to FIG. 9A-9C, a write line-level dielectric layer 92 can be deposited over the two-dimensional array of first pillar structures 1841, and line trenches laterally extending along the second horizontal direction hd2 can be formed through the write line-level dielectric layer 92. A metal material composed primarily of a heavy elemental metal, such as an elemental metal having an atomic number in a range from 72 to 79, can be deposited in the line trenches, and excess portions of the metal material may be removed from above the horizontal plane including the top surface of the write line-level dielectric layer 92. The metal is selected from hafnium, tantalum, tungsten, rhenium, osmium, iridium, platinum, or gold. Each remaining portion of the metal material that fills a respective line trench constitutes a first write line 90.

In an alternative embodiment, instead of using the above-described damascene process to form the first write lines 90, these lines may be formed by a pattern and etch process. In the pattern and etch process, a continuous metal layer is deposited on the first pillar structures 1841 and then patterned into the first write lines 90 by photolithography and etching. The first write line-level dielectric layer 92 is then deposited between the first write lines 90 and optionally planarized with the top surfaces of the first write lines 90.

The first write line 90 functions as the SOT layer (e.g., bit line) of the bottom pinned SOT memory cell 180 that also includes the respective first pillar structure 1841. The combination of each first pillar structure 1841 and the respective overlying write line 90 comprises a bottom pinned SOT memory cell 180B.

Generally, the first write lines 90 are formed over the two-dimensional array of first pillar structures 1841. The first write lines 90 can be formed on top surfaces of the two-dimensional array of first pillar structures 1841. The first write lines 90 laterally extend along the second horizontal direction hd2, and are laterally spaced apart from each other along the first horizontal direction hd1. Each of the first magnetic tunnel junctions 130 located in the respective first pillar structures 1841 comprises a respective first reference layer 132, a respective first tunneling barrier layer 134, and a respective first free layer 136 that is in contact with a respective one of the first write lines 90. Each of the first write lines 90 can be formed directly on a column of a respective subset of the first free layers 136. In one embodiment, each of the first write lines 90 comprises a second metal having an atomic number in a range from 72 to 79 at a respective second atomic percentage greater than 50%, and/or greater than 90%, and/or greater than 99%. In one embodiment, the first write lines 90 may consist essentially of tungsten. Alternatively, the first write lines 90 comprises a 2-dimensional material, such as molybdenum disulfide (MoS₂), tungsten disulfide (WS₂), graphene, etc., that can induce the spin Hall effect in the free layers 136.

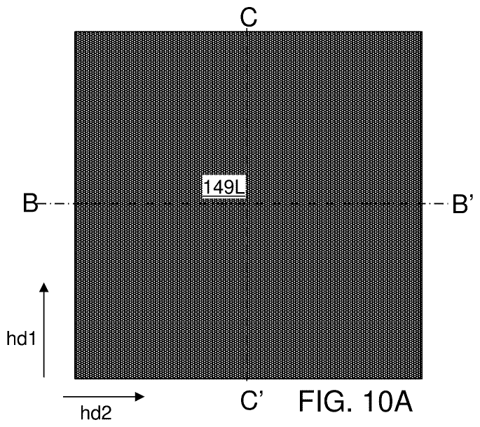

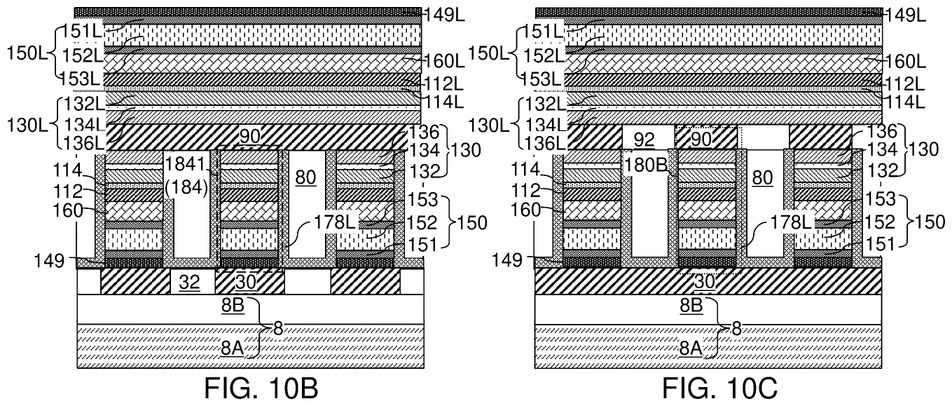

Referring to FIGS. 10A-10C, second pillar material layers (130L, 114L, 112L, 160L, 150L, 149L) can be deposited over the second read lines 30. The second pillar material layers (130L, 114L, 112L, 160L, 150L, 149L) may comprise, from bottom to top, second magnetic tunnel junction layers 130L, a second continuous antiferromagnetic coupling layer 114L, a second continuous synthetic antiferromagnetic layer 112L, second selector-level material layers (160L, 150L), and an optional second metallic adhesion layer 149L. The second magnetic tunnel junction layers 130L include, from bottom to top, a second continuous free layer 136L, a second continuous tunneling dielectric layer 134L, and a second continuous reference layer 132L. The second selector material layers 150L can comprise, from bottom to top, a proximal selector electrode material layer 153L, a non-Ohmic material layer 152L, and a distal selector electrode material layer 151L.

Generally, the second magnetic tunnel junction layers 130L may have the same set of component layers as the first magnetic tunnel junction layers 130L described above, except for the modification of the order of the component layers from bottom to top. Thus, the second magnetic tunnel junction layers 130L include, from bottom to top, a second continuous free layer 136L, a second continuous tunneling dielectric layer 134L, and a second continuous reference layer 132L, whereas the first magnetic tunnel junction layers 130L described above include, from bottom to top, a first continuous reference layer 132L, a first continuous tunneling dielectric layer 134L, and a first continuous free layer 136L.

Likewise, the second continuous antiferromagnetic coupling layer 114L may have the same material composition and the same thickness as the first continuous antiferromagnetic coupling layer 114L described above; the second continuous synthetic antiferromagnetic layer 112L may have the same material composition and the same thickness as the first continuous synthetic antiferromagnetic layer 112L described above; the second electrically conductive layer 160L may have the same material composition and the same thickness as the first electrically conductive layer 160L described above; and the optional second metallic adhesion layer 149L may have the same material composition and the same thickness as the first metallic adhesion layer 149L described above. In addition, the second selector material layers 150L may have the same set of component layers as the first selector material layers 150L described above, except for the modification of the order of the component layers from bottom to top. In one embodiment, the second pillar material layers (130L, 114L, 112L, 160L, 150L, 149L) may be identical to the first pillar material layers (149L, 150L, 160L, 112L, 114L, 130L) described above except that the order of the component layers along the vertical direction is reversed.

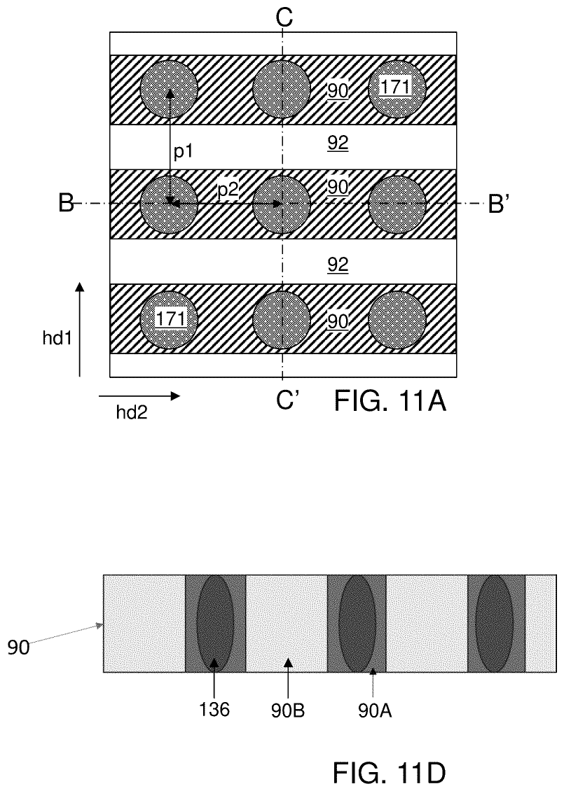

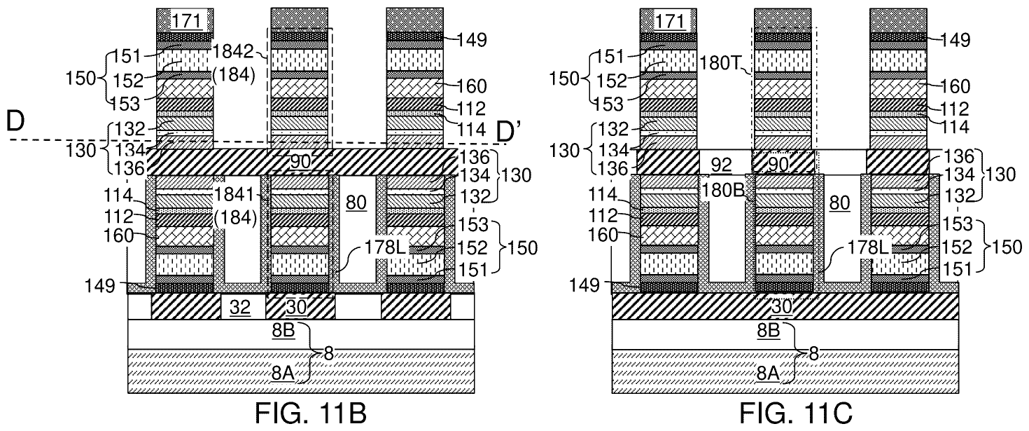

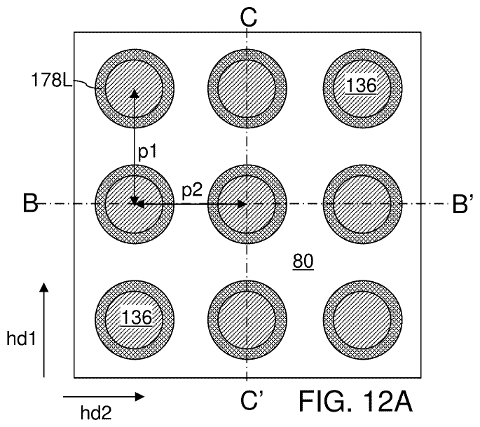

Referring to FIGS. 11A-11C, the processing steps described with reference to FIGS. 4A-4C and 5A-5C can be performed, with any needed changes, to pattern the second pillar material layers (130L, 114L, 112L, 160L, 150L, 149L) into a two-dimensional array of second pillar structures 1842 and to form a two-dimensional array of second hard mask plates 171 over the two-dimensional array of second pillar structures 1842. The changes in the processing steps may include the order of various anisotropic etch processes employed to etch the component layers within the second pillar material layers (130L, 114L, 112L, 160L, 150L, 149L). Generally, each of the second pillar structures 1842 may have a same set of structural components as a first pillar structure 1841. However, the order of the structural components within each second pillar structure 1842 along the upward vertical direction is reversed relative to the order of the structural components within each first pillar structure 1841. The combination of each second pillar structure 1842 and the respective underlying write line 90 comprises a top pinned SOT memory cell 180T. The top pinned SOT memory cell 180T shares the write line (i.e., the SOT layer) 90 with the underlying bottom pinned SOT memory cell 180B.

Generally, a two-dimensional array of second pillar structures 1842 can be formed over the first write lines 90. Each of the second pillar structures 1842 comprises a respective vertical stack including, from bottom to top, a respective second magnetic tunnel junction 130 and a respective second selector element 150. The two-dimensional array of second pillar structures 1842 can be formed on top surfaces of the first write lines 90. Each of the second magnetic tunnel junctions 130 comprises, from top to bottom, a respective second reference layer 132, a respective second tunneling barrier layer 134, and a respective second free layer 136 that is formed directly on, and is in contact with, a respective one of the first write lines 90.

In one embodiment, each of the first pillar structures 1841 and the second pillar structures 1842 is elongated along the first horizontal direction hd1. In one embodiment, each of the second pillar structures 1842 comprises a respective second straight sidewall that extends from a top surface of a respective one of the first write lines 90 to a bottom surface of a respective one of the second read lines 30. Each of the first write lines 90 is in contact with top surfaces of first free layers 136 of a respective row of first pillar structures 1841 within the two-dimensional array of first pillar structures 1841, and is in contact with bottom surfaces of second free layers 136 of a respective row of second pillar structures 1842 within the two-dimensional array of second pillar structures 1842.

FIG. 11D is a top down view along horizontal plane D-D′ of FIG. 11B according to an alternative embodiment of the present disclosure, In this alternative embodiment, the first write lines 90 may comprise composite write lines containing alternating first portions 90A and second portions 90 that alternate along the second horizontal direction hd2. The first portions 90A comprise the SOT material described above that can induce the spin Hall effect in the free layers 136, such as a refractory metal or alloy or a two dimensional material. The second portions 90B comprise an electrically conductive material having a higher electrical conductivity than the SOT material of the first portions 90A. The second portions 90B may comprise copper, copper alloys, aluminum, gold, silver, etc. Thus, the first and second portions comprise a different electrically conductive material from each other. The first portions 90A contact the free layers 136 (e.g., from the top or from the bottom). The second portions 90B enhance the electrical conductivity of the first write lines 90.

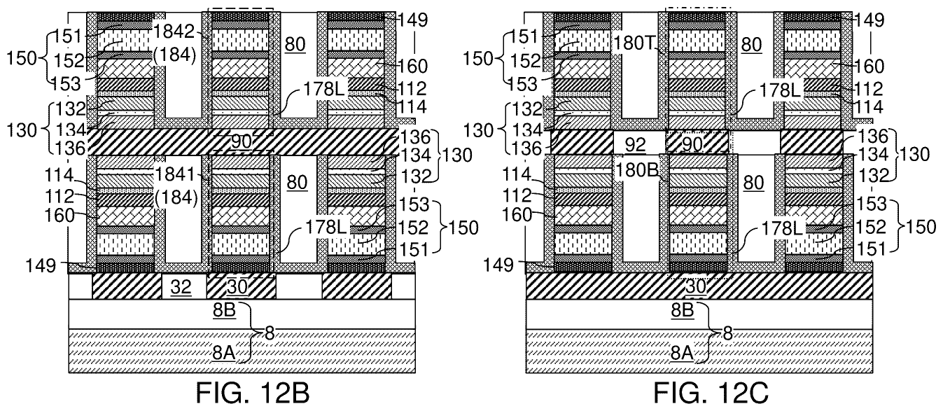

Referring to FIGS. 12A-12C, the processing steps described with reference to FIGS. 7A-7C and 8A-8C can be performed, with any needed changes, to deposit and planarize an optional second dielectric diffusion barrier layer 178L and a second dielectric matrix layer 80, to vertically recess the second dielectric matrix layer 80, and to remove the two-dimensional array of second hard mask plates 171.

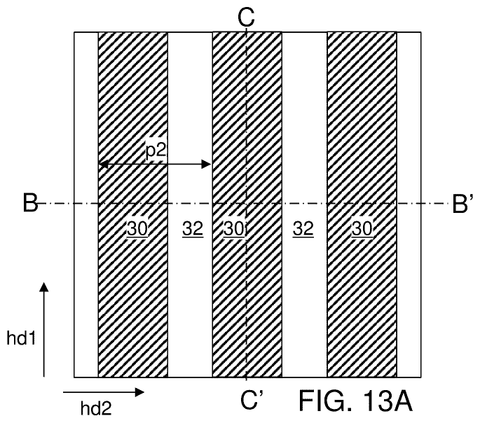

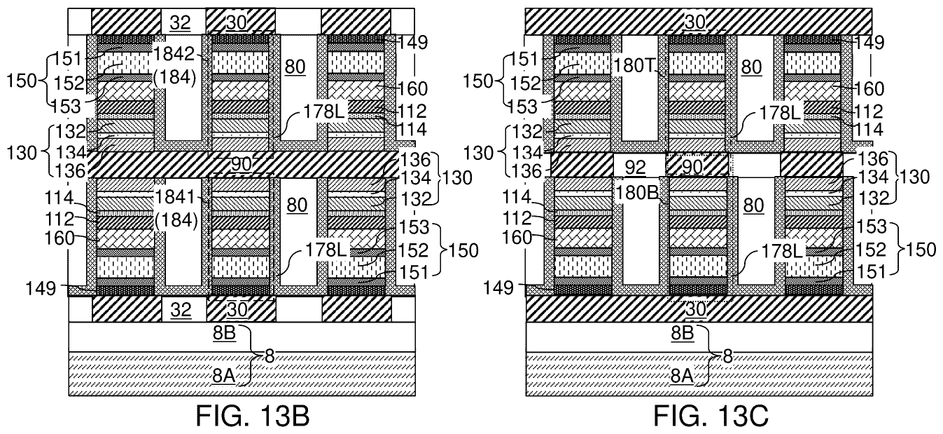

Referring to FIGS. 13A-13C, a second read line-level dielectric layer 32 can be deposited over the two-dimensional array of second pillar structures 1842, and line trenches laterally extending along the first horizontal direction hd1 can be formed through the second read line-level dielectric layer 32. The line trenches may have the same areas as the first read lines 30 in a plan view such as a top-down view. A conductive material can be deposited in the line trenches, and excess portions of the conductive material can be removed from above the horizontal plane including the top surface of the second read line-level dielectric layer 32.

Remaining portions of the conductive material filling the line trenches constitute second read lines 30. The second read lines 30 comprise, and/or consist essentially of, a nonmagnetic electrically conductive material such as Al, Cu, W, Ru, Mo, Nb, Ti, Ta, TiN, TaN, WN, MoN, or combinations thereof. The thickness of the second read lines 30 can be in a range from 20 nm to 100 nm, although lesser and greater thicknesses can also be employed.

Alternatively, instead of using the above-described damascene process to form the second read lines 30, these lines may be formed by a pattern and etch process. In the pattern and etch process, a continuous electrically conductive layer is patterned into the second read lines 30 by photolithography and etching. The second read line-level dielectric layer 32 is then deposited between the second read lines 30 and optionally planarized with the top surfaces of the second read lines 30.

The second read lines 30 laterally extend along the first horizontal direction hd1, and may be laterally spaced apart from each other along a second horizontal direction hd2. The second read lines 30 may be formed as a one-dimensional periodic array of second read lines 30 having the second pitch p2 along the second horizontal direction hd2.

Generally, the second read lines 30 can be formed over and directly on top surfaces of the two-dimensional array of second pillar structures 1842. In one embodiment, each of the second selector elements 150 is in contact with a respective one of the second read lines 30. In one embodiment, within each of the second pillar structures 1842, the respective second selector element 150 overlies the respective second magnetic tunnel junction 130. In one embodiment, each of the second selector elements 150 comprises a respective second ovonic threshold switch which comprises the non-Ohmic selector material plate 152.

In one embodiment, each of the first selector elements 150 is formed directly on a top surface of a respective one of the first read lines 30; and each of the second read lines 30 is formed directly on top surfaces of a respective subset of the second selector elements 150. In one embodiment, each of the first read lines 30 and the second read lines 30 comprises a first metal selected from Cu or Al at a respective first atomic percentage greater than 50%; and each of the first write lines 90 comprises a second metal having an atomic number in a range from 72 to 79 (e.g., tungsten) at a respective second atomic percentage greater than 50%.

Referring to FIGS. 14A and 14B, the processing steps described with reference to FIGS. 3A-13C may be repeated as many times as needed to form additional two-dimensional arrays of pillar structures 184, additional write lines 90, and additional read lines 30. Generally, the set of structural components formed employing the processing steps described with reference to FIGS. 3A-13C constitute a unit of repetition. The total number of units of repetition that can be formed above the exemplary structure illustrated in FIGS. 13A-13C may be in a range from 0 to 128, although a greater number of repetitions may also be employed. It should be noted that some optional components are omitted in the exemplary structures illustrated in FIGS. 14A and 14B. One end of each of the write lines 90 is electrically connected to a respective transistor selector element 250, while the other end of each of the write lines 90 may be grounded. In one embodiment, the transistor selector element 250 may be located in the programming circuitry 570 shown in FIG. 1.

The exemplary structure shown in FIGS. 14A and 14B comprises a two-dimensional array of third pillar structures 1843 located on top surfaces of the second read lines 30, wherein each of the third pillar structures 1843 comprises a respective vertical stack including a respective third selector element 150 and a respective third magnetic tunnel junction 130; and second write lines 90 located on top surfaces of the two-dimensional array of third pillar structures 1843 and laterally extending along the second horizontal direction hd2 and laterally spaced apart from each other along the first horizontal direction hd1. A two-dimensional array of fourth pillar structures 1844 is located on top surfaces of the second write lines 90. Each of the fourth pillar structures 1844 comprises a respective vertical stack including, from bottom to top, a respective fourth magnetic tunnel junction 130 and a respective fourth selector element 150. Third read lines 30 can be formed on top surfaces of the two-dimensional array of fourth pillar structures 1844. The third read lines 30 laterally extend along the first horizontal direction hd1 and laterally spaced apart from each other along the second horizontal direction hd2.

Generally, 2N two-dimensional arrays of pillar structures 184 can be formed, in which N is a positive integer. For each integer i that is not greater than N and greater than 1, i-th read lines 30 can be formed on a two-dimensional array of 2(i−1)-th pillar structures 184. A two-dimensional array of (2i−1)-th pillar structures 184 can be formed on the i-th read lines 30. I-th write lines 90 can be formed on the two-dimensional array of (2i−1)-th pillar structures 184. A two-dimensional array of 2i-th pillar structures 184 can be formed on the i-th write lines 90. (I+1)-th read lines can be formed on the two-dimensional array of 2i-th pillar structures 184.

Referring to FIG. 14A, a method of operating the magnetoresistive memory array comprises applying an activation voltage greater than a threshold voltage to a selected read line 30S of a selected SOT memory cell 180S, applying a deactivation voltage to unselected read lines of unselected SOT memory cells 180 which share a common selected write line 90S with the selected SOT memory cell 180S, and applying a write current to a selected write line 90S to program a selected first magnetic tunnel junction 130S (e.g., written memory bit) of the selected SOT memory cell 180S by a spin Hall effect. The activation voltage may comprise a positive voltage greater than the threshold voltage of the selected SOT memory cell 180S. The deactivation voltage may comprise a negative voltage.

Referring to FIG. 14B, the method may also include applying a read voltage greater than the threshold voltage to the selected read line 30S, and applying a read current less than the write current to the selected write line 90S to read the selected magnetic tunnel junction 130S (e.g., read memory bit) of the selected SOT memory cell 180S by the TMR effect.

In one embodiment, a magnetoresistive memory device 500 includes a substrate 8, a bottom pinned spin-orbit torque (SOT) memory cell 180B located over the substrate 8, and including a first magnetic tunnel junction 130 and a common SOT layer 90 located on the first magnetic tunnel junction 130, and a top pinned SOT memory cell 180T located over the bottom pinned SOT memory cell 180B, and including a second magnetic tunnel junction 130 located on the common SOT layer 90. The common SOT layer 90 is shared between the top pinned SOT memory cell 180T and the bottom pinned SOT memory cell 180B.

In one embodiment, the memory device also includes a first read line 30 contacting the first magnetic tunnel junction 130, wherein the first read line located between the substrate 8 and the first magnetic tunnel junction; and a second read line 30 contacting the second magnetic tunnel junction 130, wherein the second tunnel junction is located above the second magnetic tunnel junction. The memory device also includes a first two-terminal selector element 150 located in series between the first read line and the first magnetic tunnel junction; and a second two-terminal selector 150 element located in series between the second read line and the second magnetic tunnel junction.

In one embodiment, the common SOT layer 90 comprises a nonmagnetic metal write line which is electrically connected to a transistor selector element 250. The first magnetic tunnel junction 130 comprises a ferromagnetic first reference layer 132 located over the first two-terminal selector element 150, a first tunneling dielectric layer 134 located over the first reference layer 132, and a ferromagnetic first free layer 136 located over the first tunneling dielectric layer 134 and contacting a bottom horizontal surface of the common SOT layer 90. The second magnetic tunnel junction 130 comprises a ferromagnetic second free layer 136 located on a top horizontal surface of the common SOT layer 90, a second tunneling dielectric layer 134 located over the second free layer 136, and a ferromagnetic second reference layer 132 located over the second tunneling dielectric layer 134. The first two-terminal selector element 150 comprises a first ovonic threshold switch element; and the second two-terminal selector element 150 comprises a second ovonic threshold switch element.

Referring to all drawings and according to various embodiments of the present disclosure, a magnetoresistive memory device 500 comprises: first read lines 30 laterally extending along a first horizontal direction hd1 and laterally spaced apart from each other along a second horizontal direction hd2; a two-dimensional array of first pillar structures 1841 located on top surfaces of the first read lines 30, wherein each of the first pillar structures 1841 comprises a respective vertical stack including a respective first selector element 150 and a respective first magnetic tunnel junction 130; first write lines 90 located on top surfaces of the two-dimensional array of first pillar structures 1841 and laterally extending along the second horizontal direction hd2 and laterally spaced apart from each other along the first horizontal direction hd1; a two-dimensional array of second pillar structures 1842 located on top surfaces of the first write lines 90, wherein each of the second pillar structures 1842 comprises a respective vertical stack including a respective second magnetic tunnel junction 130 and a respective second selector element 150; and second read lines 30 located on top surfaces of the two-dimensional array of second pillar structures 1842 and laterally extending along the first horizontal direction hd1 and laterally spaced apart from each other along the second horizontal direction hd2, wherein each of the first magnetic tunnel junctions 130 comprises a respective first reference layer 132, a respective first tunneling barrier layer 134, and a respective first free layer 136 that is in contact with a respective one of the first write lines 90.

In one embodiment, each of the second magnetic tunnel junctions 130 comprises a respective second reference layer 132, a respective second tunneling barrier layer 134, and a respective second free layer 136 that is in contact with a respective one of the first write lines 90. In one embodiment, each of the first pillar structures 1841 further comprises a respective synthetic antiferromagnetic structure 112 that is antiferromagnetically coupled to the respective first reference layer 132. In one embodiment, within each of the first pillar structures 1841, the respective synthetic antiferromagnetic structure 112 is located between the respective first reference layer 132 and the first selector element 150.

In one embodiment, each of the first selector elements 150 is in contact with a respective one of the first read lines 30; and each of the second selector elements 150 is in contact with a respective one of the second read lines 30. In one embodiment, within each of the first pillar structures 1841, the respective first selector element 150 underlies the respective first magnetic tunnel junction 130; and, within each of the second pillar structures 1842, the respective second selector element 150 overlies the respective second magnetic tunnel junction 130. In one embodiment, each of the first selector elements 150 comprises a respective first ovonic threshold switch element 152; and each of the second selector elements comprises a respective second ovonic threshold switch element 152.

In one embodiment, each of the first write lines 90 is in contact with top surfaces of first free layers 136 of a respective row of first pillar structures 1841 within the two-dimensional array of first pillar structures 1841, and is in contact with bottom surfaces of second free layers 136 of a respective row of second pillar structures 1842 within the two-dimensional array of second pillar structures 1842. In one embodiment, each of the first pillar structures 1841 comprises a respective first straight sidewall that extends from a top surface of a respective one of the first read lines 30 to a bottom surface of a respective one of the first write lines 90; and each of the second pillar structures 1842 comprises a respective second straight sidewall that extends from a top surface of a respective one of the first write lines 90 to a bottom surface of a respective one of the second read lines 30. In one embodiment, each of the first read lines 30 and the second read lines 30 comprises a first metal selected from Cu or Al at a respective first atomic percentage greater than 50%; and each of the first write lines 90 comprises a second metal having an atomic number in a range from 72 to 79 at a respective second atomic percentage greater than 50%. In one embodiment, each of the first pillar structures 1841 and the second pillar structures 1842 is elongated along the first horizontal direction hd1.

In one embodiment, the magnetoresistive memory device comprises: a two-dimensional array of third pillar structures 1843 located on top surfaces of the second read lines 30, wherein each of the third pillar structures 1843 comprises a respective vertical stack including a respective third selector element 150 and a respective third magnetic tunnel junction 130; and second write lines 90 located on top surfaces of the two-dimensional array of second pillar structures 1842 and laterally extending along the second horizontal direction hd2 and laterally spaced apart from each other along the first horizontal direction hd1. In one embodiment, a two-dimensional array of fourth pillar structures 1844 can be located on top surfaces of the second write lines 90. Each of the fourth pillar structures 1844 comprises a respective vertical stack including a respective fourth magnetic tunnel junction 130 and a respective fourth selector element 15. Third read lines 30 can be located on top surfaces of the two-dimensional array of fourth pillar structures 1844, can laterally extend along the first horizontal direction hd1, and can be laterally spaced apart from each other along the second horizontal direction hd2.

The three dimensional crosspoint array configuration of the magnetoresistive memory array of the embodiments of the present disclosure increases the density of the memory cells compared to traditional SOT-MRAM configurations without necessarily reducing bit size or pitch, thus addressing a critical limitation in scaling down SOT-MRAM arrays. The magnetoresistive memory array of the embodiments of the present disclosure integrates both top-pinned and bottom-pinned SOT MRAM bits (i.e., top and bottom pinned SOT memory cells 180T and 180B), which share common write line 90 (which functions as a shared spin-orbit torque (SOT) layer of both cells) to increase device density.

Although the foregoing refers to particular preferred embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Whenever two or more elements are listed as alternatives in a same paragraph or in different paragraphs, a Markush group including a listing of the two or more elements is also impliedly disclosed. Whenever the auxiliary verb “can” is employed in this disclosure to describe formation of an element or performance of a processing step, an embodiment in which such an element or such a processing step is not performed is also expressly contemplated, provided that the resulting apparatus or device can provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Where an embodiment employing a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. If publications, patent applications, and/or patents are cited herein, each of such documents is incorporated herein by reference in their entirety.

What is claimed is:

1. A magnetoresistive memory device, comprising:
a substrate;
a bottom pinned spin-orbit torque (SOT) memory cell located over the substrate, and comprising a first magnetic tunnel junction and a common SOT layer located on the first magnetic tunnel junction; and
top pinned SOT memory cell located over the bottom pinned SOT memory cell, and comprising a second magnetic tunnel junction located on the common SOT layer, wherein the common SOT layer is shared between the top pinned SOT memory cell and the bottom pinned SOT memory cell.

2. The magnetoresistive memory device of claim 1, further comprising:
a first read line contacting the first magnetic tunnel junction, wherein the first read line located between the substrate and the first magnetic tunnel junction; and
a second read line contacting the second magnetic tunnel junction, wherein the second tunnel junction is located above the first magnetic tunnel junction.

3. The magnetoresistive memory device of claim 2, further comprising:
a first two-terminal selector element located in series between the first read line and the first magnetic tunnel junction; and
a second two-terminal selector element located in series between the second read line and the second magnetic tunnel junction.

4. The magnetoresistive memory device of claim 3, wherein:
the common SOT layer comprises a nonmagnetic metal write line which is electrically connected to a transistor selector element;
the second magnetic tunnel junction comprises a ferromagnetic first reference layer located over the first two-terminal selector element, a first tunneling dielectric layer located over the first reference layer, and a ferromagnetic first free layer located over the first tunneling dielectric layer and contacting a bottom horizontal surface of the common SOT layer;
the second magnetic tunnel junction comprises a ferromagnetic second free layer located on a top horizontal surface of the common SOT layer, a second tunneling dielectric layer located over the second free layer, and a ferromagnetic second reference layer located over the second tunneling dielectric layer;
the first two-terminal selector element comprises a first ovonic threshold switch element; and
the second two-terminal selector element comprises a second ovonic threshold switch element.

5. A magnetoresistive memory device, comprising:
first read lines laterally extending along a first horizontal direction and laterally spaced apart from each other along a second horizontal direction;
a two-dimensional array of first pillar structures located on top surfaces of the first read lines, wherein each of the first pillar structures comprises a respective vertical stack including a respective first selector element and a respective first magnetic tunnel junction;
first write lines located on top surfaces of the two-dimensional array of first pillar structures and laterally extending along the second horizontal direction and laterally spaced apart from each other along the first horizontal direction;
a two-dimensional array of second pillar structures located on top surfaces of the first write lines, wherein each of the second pillar structures comprises a respective vertical stack including a respective second magnetic tunnel junction and a respective second selector element; and
second read lines located on top surfaces of the two-dimensional array of second pillar structures and laterally extending along the first horizontal direction and laterally spaced apart from each other along the second horizontal direction,
wherein each of the first magnetic tunnel junctions comprises a respective first reference layer, a respective first tunneling barrier layer, and a respective first free layer that is in contact with a respective one of the first write lines.

6. The magnetoresistive memory device of claim 5, wherein each of the second magnetic tunnel junctions comprises a respective second reference layer, a respective second tunneling barrier layer, and a respective second free layer that is in contact with a respective one of the first write lines.

7. The magnetoresistive memory device of claim 5, wherein each of the first pillar structures further comprises a respective synthetic antiferromagnetic structure that is antiferromagnetically coupled to the respective first reference layer, and that is located between the respective first reference layer and the first selector element.

8. The magnetoresistive memory device of claim 5, wherein:
each of the first selector elements is in contact with a respective one of the first read lines;
each of the second selector elements is in contact with a respective one of the second read lines;
within each of the first pillar structures, the respective first selector element underlies the respective first magnetic tunnel junction;
within each of the second pillar structures, the respective second selector element overlies the respective second magnetic tunnel junction;
each of the first selector elements comprises a respective first ovonic threshold switch element; and
each of the second selector elements comprises a respective second ovonic threshold switch element.

9. The magnetoresistive memory device of claim 5, wherein each of the first write lines is in contact with top surfaces of first free layers of a respective row of first pillar structures within the two-dimensional array of first pillar structures, and is in contact with bottom surfaces of second free layers of a respective row of second pillar structures within the two-dimensional array of second pillar structures.

10. The magnetoresistive memory device of claim 5, wherein:
each of the first pillar structures comprises a respective first straight sidewall that extends from a top surface of a respective one of the first read lines to a bottom surface of a respective one of the first write lines; and
each of the second pillar structures comprises a respective second straight sidewall that extends from a top surface of a respective one of the first write lines to a bottom surface of a respective one of the second read lines.

11. The magnetoresistive memory device of claim 5, wherein:
each of the first read lines and the second read lines comprises a first metal selected from Cu or Al at a respective first atomic percentage greater than 50%; and
each of the first write lines comprises a second metal having an atomic number in a range from 72 to 79 at a respective second atomic percentage greater than 50% or a two dimensional material that can induce the spin Hall effect in the first free layers.

12. The magnetoresistive memory device of claim 5, wherein:
each of the first write lines comprises alternating first portions and second portions which alternate along the second horizontal direction;
the first portions contacts the first free layers of the respective first magnetic tunnel junctions;
the first portions comprises a material that can induce the spin Hall effect in the free layer; and
the second portions comprise an electrically conductive material having a higher electrical conductivity than the material of the first portions.

13. The magnetoresistive memory device of claim 5, wherein each of the first pillar structures and the second pillar structures is elongated along the first horizontal direction.

14. The magnetoresistive memory device of claim 5, further comprising:
a two-dimensional array of third pillar structures located on top surfaces of the second read lines, wherein each of the third pillar structures comprises a respective vertical stack including a respective third selector element and a respective third magnetic tunnel junction;
second write lines located on top surfaces of the two-dimensional array of second pillar structures and laterally extending along the second horizontal direction and laterally spaced apart from each other along the first horizontal direction;
a two-dimensional array of fourth pillar structures located on top surfaces of the second write lines, wherein each of the fourth pillar structures comprises a respective vertical stack including a respective fourth magnetic tunnel junction and a respective fourth selector element; and
third read lines located on top surfaces of the two-dimensional array of fourth pillar structures and laterally extending along the first horizontal direction and laterally spaced apart from each other along the second horizontal direction.

15. A method of operating the magnetoresistive memory device of claim 5, comprising:
applying an activation voltage greater than a threshold voltage to a selected first read line of the first read lines;
applying a deactivation voltage to unselected first read lines of the first read lines; and
applying a write current to a selected write line of the first write lines to program a selected first magnetic tunnel junction by a spin Hall effect.

16. The method of claim 15, further comprising:
applying a read voltage greater than a threshold voltage to the selected first read line; and
applying a read current less than the write current to the selected write current to read the selected magnetic tunnel junction.

17. A method of forming a memory array, comprising:
forming first read lines laterally extending along a first horizontal direction and laterally spaced apart from each other along a second horizontal direction over a substrate;
forming a two-dimensional array of first pillar structures over the first read lines, wherein each of the first pillar structures comprises a respective vertical stack including a respective first selector element and a respective first magnetic tunnel junction, and wherein each of the first magnetic tunnel junctions comprises a respective first reference layer, a respective first tunneling barrier layer, and a respective first free layer;
forming first write lines over the two-dimensional array of first pillar structures, wherein the first write lines laterally extend along the second horizontal direction and are laterally spaced apart from each other along the first horizontal direction, and wherein each of the first write lines is formed directly on a column of a respective subset of the first free layers;
forming a two-dimensional array of second pillar structures over the first write lines, wherein each of the second pillar structures comprises a respective vertical stack including a respective second magnetic tunnel junction and a respective second selector element; and
forming second read lines over the two-dimensional array of second pillar structures, wherein the second read lines laterally extend along the first horizontal direction and are laterally spaced apart from each other along the second horizontal direction.

18. The method of claim 17, wherein:
each of the second magnetic tunnel junctions comprises a respective second reference layer, a respective second tunneling barrier layer, and a respective second free layer; and
each of the second free layers is formed directly on a respective one of the first write lines.

19. The method of claim 17, wherein:
each of the first selector elements is formed directly on a top surface of a respective one of the first read lines; and
each of the second read lines is formed directly on top surfaces of a respective subset of the second selector elements.

20. The method of claim 17, wherein:
each of the first read lines and the second read lines comprises a first metal selected from Cu or Al at a respective first atomic percentage greater than 50%; and
each of the first write lines comprises a second metal having an atomic number in a range from 72 to 79 at a respective second atomic percentage greater than 50%.
